(19) United States
(12) Patent Application Publication
(10) Pub. No.: US 2009/0260598 A1
(43) Pub. Date: Oct. 22, 2009

(54) ARRANGEMENT WITH A PIEZOELECTRIC ACTUATOR AROUND WHICH FLUID MEDIA FLOW

(76) Inventor: Nadja Eisenmenger, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/300,548

(22) PCT Filed: May 11, 2007
(86) PCT No.: PCT/EP07/54591

§ 371 Date: Nov. 12, 2008

(30) Foreign Application Priority Data
May 17, 2006 (DE) 10-2006-022-998.3

(51) Int. Cl. F02M 51/00; H01L 41/053; B05B 1/08

(52) U.S. Cl. 123/494; 310/340; 239/102.2; 239/585.1

(57) ABSTRACT

An arrangement with a piezoelectric actuator is disclosed, made up of a piezoelectric element with a multilayer construction of piezoelectric layers. The piezoelectric actuator is surrounded by an inner chamber at least surrounding the layers, which filled with a fluid insulation medium. The inner chamber is sealed from a fluid medium in an outer chamber an elastic sleeve which can change shape. The sleeve is sealed with sealing elements being provided at the axial ends thereof in the region of an actuator base and an actuator head. By a shape and/or positional change of the sealing elements, corresponding to the elasticity of the sleeve, a volume equalization in the inner chamber with the insulation medium is achieved.

The invention relates to an arrangement with a piezoelectric actuator around which fluid media flow, for example a piezoelectric actuator in injection systems for internal combustion engines, with the defining characteristics of the preamble to the main claim.

### PRIOR ART

It is intrinsically known that the above-mentioned piezoelectric actuator can be constructed using a piezoelectric element in such a way that by utilizing the so-called piezoelectric effect, it is possible to carry out a valve needle stroke control or the like. The piezoelectric element is composed of a material with a suitable crystalline structure so that when an external voltage is applied, a mechanical reaction of the piezoelectric element occurs, which, depending on the crystalline structure and the application region of the electric voltage, represents a compression or a tension in a predeterminable direction. Piezoelectric actuators of this kind are suitable, for example, for applications in which stroke motions occur with powerful actuation forces and at high clock frequencies.

DE 10026005 A1, for example, has disclosed using a piezoelectric actuator of this kind as a component of a piezo injector, which component can be used for triggering the nozzle needle in injectors provided to inject fuel into the combustion chamber of an internal combustion engine. In this piezoelectric actuator, a piezoelectric element is composed of a stack of a plurality of electrically interconnected piezoceramic layers that is held in a prestressed fashion between two stops. Each piezoceramic layer is enclosed as a piezoelectric layer between two internal electrodes via which an electrical voltage can be applied from the outside. In reaction to this electrical voltage, the piezoceramic layers then each execute small respective stroke movements in the direction of the potential gradient, which add up to constitute the overall stroke of the piezoelectric actuator. This overall stroke can be changed via the magnitude of the applied voltage and can be transmitted to a mechanical actuating element.

Such known arrangements are frequently used as so-called common rail systems for delivering fuel in direct-injection diesel engines. In these systems known as common rail systems, the injection pressure can be easily adapted to the load and speed of the internal combustion engine.

These common rail injectors can be embodied so that there is a nozzle needle that is directly controlled by the piezoelectric actuator; the piezoelectric actuator is directly surrounded by the rail pressure of the fuel and only a hydraulic coupling chamber is provided between the nozzle needle and the piezoelectric actuator. The rail pressure to which the ceramic of the piezoelectric element is subjected can be up to 2000 bar. Since the piezoceramic frequently has a certain porosity or also fine fractures on its surface, it is not possible to prevent diesel fuel from penetrating into the flaws of an unprotected piezoelectric actuator. Since the piezoelectric actuator is composed of layers that are separated by positive and negative internal electrodes, it is necessary to prevent the occurrence of any electrical arcing in the event of possibly uncovered internal electrodes.

Although diesel fuel is in principal a good electrical insulator, the percentage of water contained in conventional diesel fuels can lead to such arcing, which can result in the failure of the piezoelectric actuator. In addition to the water in the diesel fuel, impurities in the diesel fuel can settle on the ceramic of the piezoelectric element and enable an electrical arcing.

In order to avoid such disadvantages, DE 10230032 A1 has disclosed an arrangement with a piezoelectric actuator around which fluid media flow, in which the ceramic layers of the piezoelectric element are cast into an insulating compound that can change shape and that is in turn inserted into a housing casing that is sealed in relation to the medium at its sides and at its upper and lower ends. In order to compensate for volume changes of the insulating compound during operation, the housing casing has waist-formed indentations over the course of its axial span.

### DISCLOSURE OF THE INVENTION

The invention is based on an arrangement with a piezoelectric actuator described the beginning, which is constructed with a piezoelectric element composed of a multilayered structure of piezoelectric layers; internal electrodes situated between the piezoelectric layers in the direction of the layer structure of the piezoelectric element are acted on in alternation with different polarities of an electrical voltage. A chamber filled with a fluid insulating medium is provided; the fluid insulating medium encompasses at least the piezoelectric layers and is sealed in relation to another fluid medium in an outer chamber by means of a sleeve that can change shape. According to the invention, the sleeve is advantageously embodied as elastic within preset limits, at least in subregions of its longitudinal span; at the axial ends of the sleeve, sealing points with sealing elements are provided in the region of an actuator foot and an actuator head and, by changing their shape and/or position in accordance with the elasticity of the sleeve, achieve a predetermined volume compensation in the chamber with the insulating medium, for example a condenser oil.

According to an advantageous embodiment, the sealing element in the region of the actuator head is situated in an axially extending annular groove in which the sealing element is axially movable for the sake of the volume compensation. The annular groove and the sealing element in this case can be simply dimensioned so that the cross section of the annular groove multiplied by the axial movement of the sealing element corresponds to the volume to be compensated for. Furthermore, the chamber with the insulating medium can also be partially filled with solid filler elements.

In an advantageous utilization, the arrangement with the piezoelectric actuator according to the invention can be a piezo injector for a fuel injection system of an internal combustion engine in which the fuel, for example diesel, flows through the outer chamber.

The advantageous use of the sleeve according to the invention thus permits the piezoceramic of the piezoelectric actuator to be simply and long-lastingly protected from impurities and water contained in the diesel fuel during operation and thus makes it possible to prevent electrical arcing between the internal electrodes. In addition to the pure protection of the ceramic, the proposed elastic encasing of the piezoelectric actuator with the sleeve assures that the ceramic of the piezoelectric actuator can execute a stroke of several μm during operation.

In any case, the connection to the actuator head and the actuator foot must be fuel-resistant and fuel-tight. In conventional coating processes, it is not possible to assure an absolutely bubble-free coating of flaws beneath the actuator surface, e.g. in the region of the electrical contacting. During operation of the piezoelectric actuator in a piezo injector, bubbles could possibly be compressed by up to 2000 bar of pressure, thus leading to mechanical stresses or even tears in the coating.

In another embodiment of the invention, the sleeve can also be an elastic tube that is attached directly to the actuator head and the actuator foot by means of corresponding sealing points. It is also possible, for example, for the sleeve to be a solid plastic sleeve, e.g. an injection-molded component, that is embodied with thinner walls in the central region than in the end regions and for the sleeve to then be attached directly to the actuator head and the actuator foot by means of corresponding sealing points. In this instance, insert parts can be inserted into the sleeve in the region of the sealing points in order to reinforce this region.

### BRIEF DESCRIPTION OF THE DRAWINGS

Exemplary embodiments of the piezoelectric actuator according to the invention will be explained in conjunction with the drawings.

FIG. 1 shows a section through an arrangement with a piezoelectric actuator in a piezo injector for fuel injection in an internal combustion engine,

FIG. 2 is a detailed view of the piezo injector according to FIG. 1, and

FIG. 3 is another modified exemplary embodiment of the piezo injector according to FIG. 1.

### EMBODIMENTS OF THE INVENTION

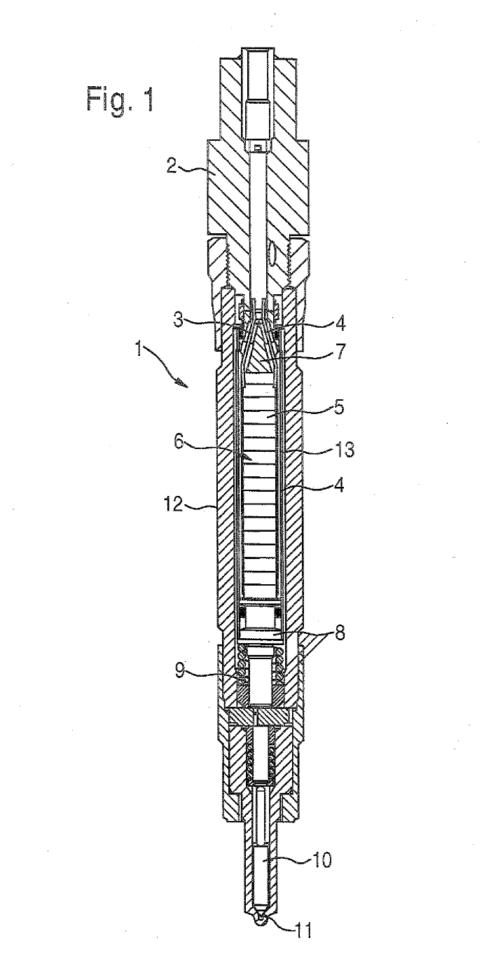

FIG. 1 shows a schematic structure of an arrangement 1 with a piezoelectric actuator that can be used, for example, to control needle stroke in the fuel injection system of an internal combustion engine. In this case, the electric supply lines 3 and 4 for the electrical voltage for the triggering of a piezoelectric element 5 are routed through an injector body 2 in the upper part of the arrangement.

The piezoelectric element 5 is a component of a piezoelectric actuator 6, which also has an actuator foot 7 and an actuator head 8. The supply lines 3 and 4 are routed to external electrodes on the piezoelectric element 5 and, when a triggering occurs through the application of a voltage, the piezoelectric element 5—by means of a mechanical arrangement that is situated vertically beneath the piezoelectric actuator 6 and in this case, is equipped with a coupler 9—acts on a nozzle needle 10 in a way that enables a nozzle port 11 to be opened.

It is thus possible, by means of the actuator module body 12, for a fuel conveyed via the inner chamber of the injector body 2 to be injected into the combustion chamber of an internal combustion engine that is not shown here. To this end, the actuator module body 12 is connected to the injector body 2 in a mechanically fixed, pressure-tight fashion. Via a fuel supply bore that is not shown here, a chamber 13 in the actuator module body 12 is completely filled with fuel, e.g. diesel fuel, at the rail pressure mentioned in the introduction to the specification.

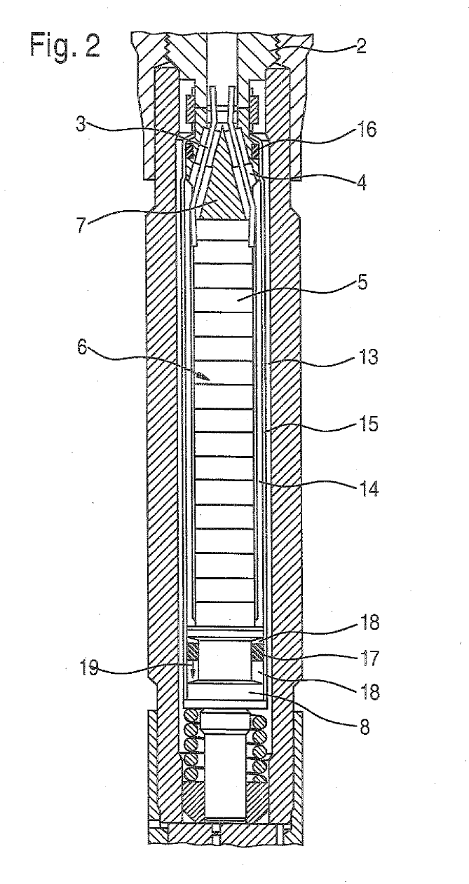

FIG. 2 is an enlarged depiction of the region with the piezoelectric actuator 6 according to FIG. 1; components that remain the same have been labeled with identical reference numerals. It should be mentioned in this connection that a chamber 14 directly encompassing the piezoelectric actuator 6 is filled with an insulating medium such as condenser oil. A sleeve 15 is provided, which, during assembly of the arrangement 1, is slid over the piezoelectric actuator 6, thus sealing the fuel in the chamber 13 in relation to the insulating medium in the chamber 14 by means of the sealing elements 16 and 17.

The pressure fluctuations in the chamber 13 occurring during operation of the arrangement 1 are thus transmitted directly to the insulating medium in the chamber 14 via the preferably thin-walled sleeve 15. Depending on how large of the volume of the chamber 14 is structurally designed to be, at pressures of up to 2000 bar and a corresponding thermal expansion in the range from −40 to +150° C., the low compressibility of the insulating medium in the chamber 14 results in volume changes in the range of several mm³.

If, as in the exemplary embodiment shown in FIG. 2, the sleeve 15 is composed of steel, then the relatively thin wall of the sleeve 15 in this case only permits compensation for small changes in volume. In this instance, an annular groove 18 for the sealing element 17 is designed so as to enable an axial movement (arrow 19) of the sealing element 17. The cross-section of the annular groove 18 multiplied by the axial movement of the sealing element 17 then corresponds to the volume that can be compensated for in the chamber 14.

With an optimal structural design of the annular groove 18 and the sleeve 15, the proposed embodiment can achieve the fact that the pressure of the medium in the chamber 13, in this case diesel fuel, is transmitted directly to the chamber 14 with the insulating medium via the sleeve 14. The requirements placed on the sealing elements 16 and 17 with regard to their sealing function are relatively low in this case.

During operation of the proposed arrangement 1 as a piezo injector for fuel, the piezoelectric actuator 6 can execute strokes in the form of longitudinal movements on an order of magnitude of up to 0.1 mm, for example. With these relatively small strokes, the actuator head 8 in the region of the sealing element 17 moves in relation to the sleeve 15. Since the stroke is relatively small in relation to the dimensions of the sealing element 17, the stroke is transmitted as a deformation or movement of the elastomer material of the sealing element 17. The sealing element 17 in this case thus functions more or less like a membrane, which is advantageous with regard to wear and the thorough mixing of the media contained in the chambers 13 and 14.

In order to provide space for the above-proposed volume compensation by means of an elongated annular groove 18 at the sealing element 17, it is also possible in another embodiment of the invention to keep the volume of the insulating medium in the chamber 14 to a minimum by means of filler elements that are not shown here.

The above-described volume change in the event of pressure and/or temperature changes of the media is always proportional to the initial volume. With unchanged external dimensions of the piezoelectric actuator 6, the relatively thin-walled sleeve 15 is always able to compensate for the same amount of the respective volume. The smaller the volume to be compensated for is, the simpler the volume compensation via the thin-walled sleeve 15 becomes.

Another possibility for volume compensation not explicitly shown here is the use of a correspondingly elastic sleeve 15, for example a length of tube that provides a seal at the actuator head 8 and the actuator foot 7 at the two axial ends. This also achieves the fact that inside the tube (corresponding to the sleeve 15), the insulating medium is contained in the chamber 14 and the rail pressure of the medium in the chamber 13 is transmitted directly to the insulating medium in the chamber 14. The sealing points of the tube at the actuator head 8 and the actuator foot 7, which sealing points are embodied in a correspondingly different fashion in this case, are not subjected to any pressure differences, which also means that no leakages can be produced since the longitudinal movement of the piezoelectric actuator 6 is absorbed directly by the elasticity of the tube.

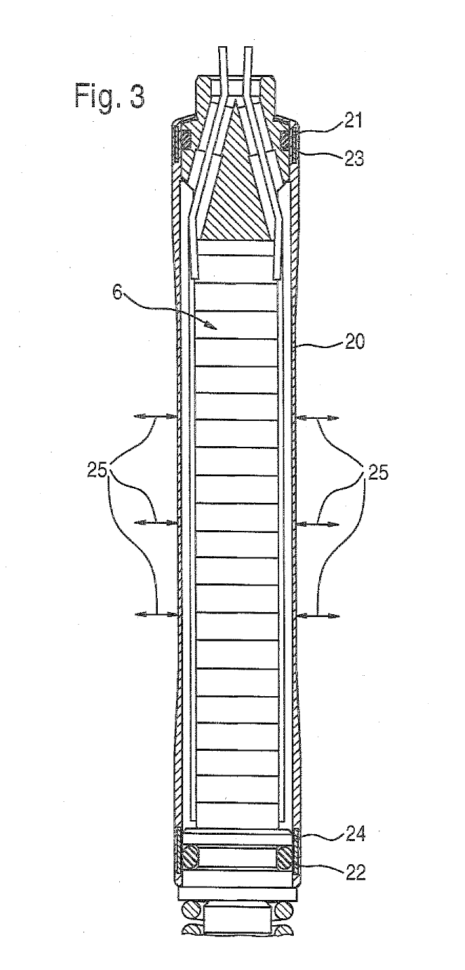

FIG. 3 shows another embodiment of the arrangement according to the invention in which a solid sleeve 20 is provided as an enclosure of the insulating medium in the chamber 13. Since a solid sleeve 20 of this kind also offers a mechanical protection of the piezoelectric actuator 6 during transport and installation, it is also possible to use an injection-molded component made of plastic as the sleeve 20, in combination with correspondingly adapted sealing elements 21 and 22.

In order to prevent the plastic of the sleeve 20 from creeping over the span of its service life and thus reducing the prestressing force on the sealing elements 21 and 22, in the exemplary embodiment shown in FIG. 3, insert parts 23 and 24 composed of metal are injection-molded into the component in the region of the sealing elements 21 and 22. The plastic sleeve 20 is embodied with walls that are thinner in the central region than at the axial ends so that a volume and pressure compensation can take place here through a diameter change in accordance with the arrows 25.

1-10. (canceled)

11. An arrangement with a piezoelectric actuator comprising:
a piezoelectric element;
an inner chamber that encompasses at least the piezoelectric element, the inner chamber being filled with a fluid insulating medium;
an outer chamber filled with a fluid medium;
a sleeve sealing the inner chamber from the fluid medium in the outer chamber, the sleeve being embodied as elastic in at least subregions of its longitudinal span; and
sealing elements disposed at sealing points at axial ends of the sleeve in a region of an actuator foot and an actuator head, wherein changing a shape and/or position of the sealing elements in accordance with an elasticity of the sleeve, provides a predetermined volume compensation in the inner chamber with the insulating medium.

12. The arrangement as recited in claim 11, wherein in the region of the actuator head, the sealing element is situated in an axially extending annular groove in which the sealing element is able to move axially in order to provide the volume compensation.

13. The arrangement as recited in claim 12, wherein the annular groove and the sealing element are dimensioned so that a cross-section of the annular groove multiplied by a length of an axial movement of the sealing element corresponds to the volume to be compensated for.

14. The arrangement as recited in claim 11, wherein the inner chamber with the insulating medium is partially filled with solid filler elements.

15. The arrangement as recited in claim 12, wherein the inner chamber with the insulating medium is partially filled with solid filler elements.

16. The arrangement as recited in claim 13, wherein the inner chamber with the insulating medium is partially filled with solid filler elements.

17. The arrangement as recited in claim 11, wherein the sleeve is an elastic tube that is attached directly to the actuator head and the actuator foot by means of corresponding sealing points.

18. The arrangement as recited in claim 11, wherein the sleeve is a solid plastic sleeve that is embodied with thinner walls in its central region than in its end regions and the sleeve is attached directly to the actuator head and the actuator foot by means of corresponding sealing points.

19. The arrangement as recited in claim 18, wherein insert parts are inserted into the sleeve in the region of the sealing points.

20. The arrangement as recited in claim 11, wherein the insulating medium in the inner chamber is a condenser oil.

21. The arrangement as recited in claim 12, wherein the insulating medium in the inner chamber is a condenser oil.

22. The arrangement as recited in claim 17, wherein the insulating medium in the inner chamber is a condenser oil.

23. The arrangement as recited in claim 18, wherein the insulating medium in the inner chamber is a condenser oil.

24. The arrangement as recited in claim 11, wherein the arrangement with the piezoelectric actuator is a piezo injector for a fuel injection system of an inner combustion engine in which the fuel flows through the outer chamber.

25. The arrangement as recited in claim 12, wherein the arrangement with the piezoelectric actuator is a piezo injector for a fuel injection system of an inner combustion engine in which the fuel flows through the outer chamber.

26. The arrangement as recited in claim 17, wherein the arrangement with the piezoelectric actuator is a piezo injector for a fuel injection system of an inner combustion engine in which the fuel flows through the outer chamber.

27. The arrangement as recited in claim 18, wherein the arrangement with the piezoelectric actuator is a piezo injector for a fuel injection system of an inner combustion engine in which the fuel flows through the outer chamber.

28. The arrangement as recited in claim 24, wherein the fuel is diesel fuel.

29. The arrangement as recited in claim 25, wherein the fuel is diesel fuel.

30. The arrangement as recited in claim 27, wherein the fuel is diesel fuel.
